(19) United States
(12) Patent Application Publication
(10) Pub. No.: US 2008/0135282 A1
(43) Pub. Date: Jun. 12, 2008

(54) PRINTED MULTILAYER CIRCUIT CONTAINING ACTIVE DEVICES AND METHOD OF MANUFATURING

(75) Inventors: Krishna D. Jonnalagadda, Algonquin, IL (US); Daniel R. Gamota, Palatine, IL (US); Iwona Turlik, Barrington, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/609,069

(22) Filed: Dec. 11, 2006

(51) Int. Cl. H05K 1/16; H05K 3/12

(52) U.S. Cl. 174/260; 29/846

(57) ABSTRACT

A printed multilayer electronic circuit has printed electronic components on a first level circuit. Electrical conductors are printed on the first level circuit, electrically connected to the electronic components. A layer of dielectric material is printed over the printed electrical conductors. The dielectric layer contains apertures or openings that extend vertically through the dielectric layer down to the electrical conductors. A second set of electrical conductors are then printed on the dielectric layer, situated around the apertures. Electrically conductive material is printed in the apertures so that an electrical connection is made from the second set of electrical conductors to the electrical conductors on the lower level. A second level circuit having additional electronic components is then formed on the dielectric layer and the second set of conductors, so that these electronic components are electrically connected to the electronic components on the first level circuit through the path of the printed second set of electrical conductors, the printed electrically conductive material, and the printed electrical conductors on the lower level.

### FIELD OF THE INVENTION

The present invention relates generally to electronic circuit substrates, and more particularly to printed electronic circuits having printed active devices and printed three dimensional interconnects and methods of manufacturing the circuits and devices using high speed roll-to-roll or sheet-fed printing processes.

### BACKGROUND

Conventional fabrication methods for manufacturing printed circuits have always utilized one or more methods of creating a conductive metal pattern on a dielectric substrate. Some of the various methods include print and etch, electroless copper deposition, vacuum deposition, and screen printing, contact printing, or ink jetting a liquid slurry of metal onto the substrate. Some of these methods are subtractive, such as the print and etch where patterns are etched from a laminated copper foil, others are purely additive, such as the printing or ink jetting methods where conductor patterns are directly formed on the substrate, and still others are combinations of additive and subtractive. In addition to forming conductor patterns for the electrical circuitry, many have also sought to create passive devices, such as resistors and capacitors, on the substrate. Resistors and capacitors have long been utilized with success in circuits with ceramic substrates, and some have even modified this technology to incorporate it into circuitry on rigid glass reinforced polymer substrates. Adoption of passive and active devices on high volume, low cost, flexible film substrates has been less successful.

Fabrication of printed electronic circuitry and devices using high speed graphic arts printing technology has the potential to produce very inexpensive circuits in very high volumes e.g. gravure, flexography. However, the lack of a simple and cost effective means to route electrical signals from one layer to another has hindered the widespread use of this technology. Currently, designers are restricted to a few cost-prohibitive options of forming a layer X to layer Y connection, such as mechanical and laser drilling, sequential lamination, and build up. Mechanically drilled vias can penetrate the entire printed multilayer electronic circuit, but they occupy space on every layer. Laser drilled blind microvias can be employed to reduce the size and cost of the printed multilayer electronic circuit, and compared to mechanical drilling, laser drilling allows much smaller vias, but they can only connect the outermost layer to the next inner layer. Furthermore, many of above processes have been developed for the traditional printed wiring board industry, are relatively slow, and are usually not compatible with high speed printing processes that can have throughput speeds of up to 2000 ft/min or 7000 sheets/hr. It is therefore highly desirable to find a means of creating high density printed multilayer circuits on flexible substrates that can interconnect circuit elements on differing levels using high speed graphic arts technology.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is a cross sectional view of a printed multilayer circuit containing active electronic devices, in accordance with some embodiments of the invention.

FIG. 2 is a plan view of the printed multilayer circuit of FIG. 1, in accordance with some embodiments of the invention.

FIG. 3 is a flow chart of one method of manufacturing a printed multilayer circuit, in accordance with some embodiments of the invention.

FIG. 4 is an isometric view of cavities in a gravure printing head, in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method and apparatus components related to multilayer printed electronic circuits using high speed roll-to-roll or sheet-fed printing processes. Accordingly, the apparatus components and methods have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processes and/or elements for manufacturing a multilayer printed electronic circuit. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such multilayer printed electronic circuits with minimal experimentation.

A printed multilayer electronic circuit comprises a number of printed electronic components on a first level circuit. One or more electrical conductors are printed on this first level circuit such that the conductors are electrically connected to at least some of the electronic components. A layer of dielectric material is then printed over the printed electrical conductors, and, optionally, over the electronic components. The dielectric layer is formed such that it contains apertures that extend vertically through the dielectric layer down to the electrical conductors. A second set of electrical conductors are then printed on the dielectric layer, such that at least some of these second electrical conductors are situated around some of the apertures. Electrically conductive material is then printed in these apertures so that an electrical connection is made from the second set of electrical conductors to the electrical conductors on the lower level. A second level circuit comprising additional electronic components are then formed on the dielectric layer and the second set of conductors, such that these electronic components are electrically connected to at least some of the electronic components on the first level circuit through the path of the printed second set of electrical conductors, the printed electrically conductive material, and the printed electrical conductors on the lower level.

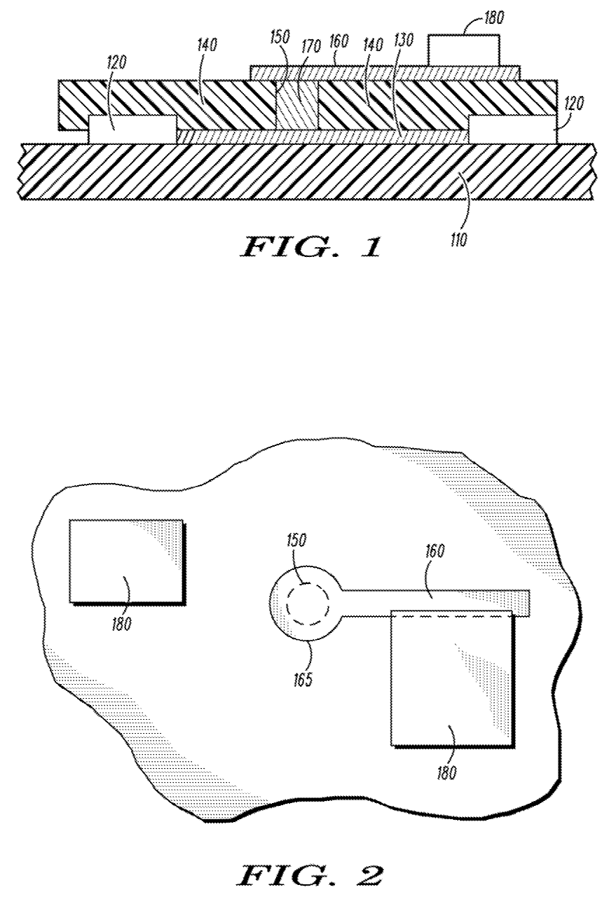

Referring now to FIG. 1, a multilayer electronic circuit is formed on a substrate 110 using high speed printing processes, such as flexography, lithography, gravure, screen, and pad printing. A first level circuit containing a plurality of printed electronic devices 120 is situated on one side of the substrate 110. The printed electronic devices can be one or more of a variety of devices such as, but not limited to, printed transistors, printed emissive pixels, printed capacitors, printed resistors, printed inverters, printed ring oscillators, and printed reflective pixels. One example of such a first level circuit would be an emissive display containing a matrix of electroluminescent pixels. A series of electrical conductors 130 that serve to provide electrical interconnections to the various electronic devices are also situated on the substrate, typically formed by a high speed printing process. A dielectric layer 140 overlies the electrical conductors 130, and optionally, the devices 120 on the first level circuit. The dielectric layer 140 does not have to cover all, or even some, of the devices 120, but in some embodiments it can cover all the devices. The dielectric layer 140 is printed in such a manner that it contains apertures 150 that extend vertically down through the layer from the top to the bottom. The apertures 150 are situated on or next to the electrical conductors 130, so that a portion of the electrical conductor is exposed by the aperture. The apertures are preferably round, but can be any shape, such as square, rectangular, polygonal, or other shapes. Apertures 150 are formed in conventional manner, as is well known to those skilled in the art of printing technology. Usually, one will employ a plurality of apertures to electrically interconnect the lower and upper circuits, but depending on the particular design, one might only find one aperture in the multilayer circuit. Over the dielectric layer 140 lies a second set of electrical conductors 160, typically formed by a high speed printing process, that will serve to provide electrical interconnections to electronic devices that will be situated on the dielectric layer. Some portions of these second electrical conductors 160 lie over or are adjacent to the apertures 150, so that when electrically conductive material 170 is printed in the apertures, an electrical connection is made by way of the printed second electrical conductors 160, the printed electrically conductive material 170, and the printed first electrical conductors 130. The electrically conductive material 170 can be printed in the apertures 150 at the same time as the second set of electrical conductors 160 are printed, or it can be printed in a later print. Finally, second level electrical circuit containing a plurality of printed electronic devices 180 is situated on top of the dielectric layer 140. The printed electronic devices can be one or more of a variety of devices such as, but not limited to, printed transistors, printed emissive pixels, printed capacitors, printed resistors, printed inverters, printed ring oscillators, and printed reflective pixels, and are electrically connected to the second set of electrical conductors 160. Thus a printed multilayer circuit is formed that connects electronic devices on a first level circuit to electronic devices on a second level circuit by means of printed conductors and printed conductive apertures. Of course, in certain situations, not all of the devices on the second level need to be connected to the devices on the first level, and vice versa, and a plethora of routing configurations can be envisioned, depending on the precise electrical design.

Referring now to FIG. 2, a plan view of the cross sectional multilayer circuit shown in FIG. 1, one configuration of the second set of electrical conductors 160 and the apertures 150 has one conductor terminating at the aperture as a round pad 165 that surrounds the aperture to form an annular ring. Also, in this instance, the dashed line depicts the hidden wall of the filled aperture 150, as the aperture is filled with electrically conductive material. When the conductors and the apertures are printed and filled at the same time, then the conductors and the conductive material in the aperture are made of the same material. Also, the dashed line under a portion of the printed electronic device 180 indicates that a portion of the electrical conductor lies under the printed device, thereby making electrical interconnect. Of course, this is only one embodiment, and electrical interconnect could be made by other means.

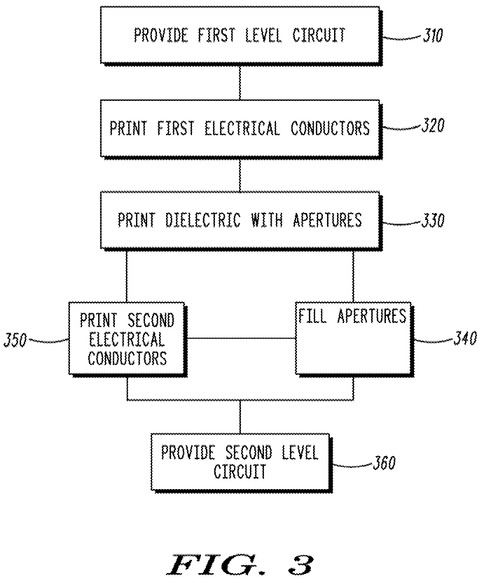

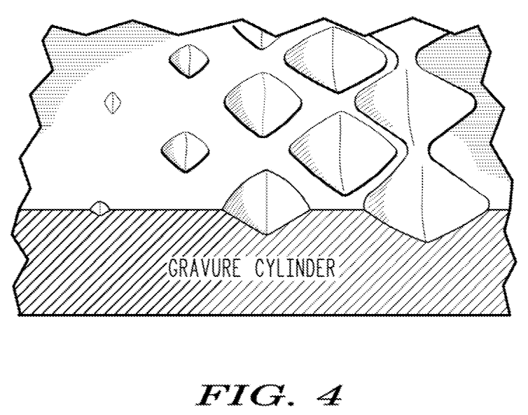

Having described one embodiment of the structure of our invention, we now turn to a description of the process used to create this structure. Referring now to FIG. 3, a substrate contains a number of printed electrical devices 310. In one embodiment, the substrate is a flexible substrate and is a very long, continuous roll, or a series of sheets. A series of electrical conductors is then printed 320 over the first level circuit using a high speed printing process, such as flexography, lithography, gravure, screen, or pad printing. A dielectric layer containing a plurality of apertures or holes that extend vertically thought he layer is then printed 330 on the substrate over the electrical conductors using a high speed printing process, such as flexography, lithography, gravure, screen, or pad printing. The apertures or holes are situated over at least some of the printed electrical conductors. The apertures are filled 340 by printing an electrically conductive material into the apertures by means of a high speed printing process, such as flexography, lithography, gravure, screen printing, or pad printing. One embodiment uses a printing head that contains an array of cavities or miniature reservoirs that serve to contain the electrically conductive material to be printed, such that the volume of each cavity varies as a function of the amount of electrically conductive material to be transferred into the aperture. By configuring the printing head to have these variable sized apertures as shown in FIG. 4, one can easily deposit larger amount of material in certain places, like the aperture, while still printing precise patterns on the surface of the dielectric. Thus, we can create a three dimensional structure by tuning the high speed printing head to the application at hand, easily filling the apertures. Our invention is applicable to any printing process that utilizes print head that have depressed, as opposed to raised, portions, for example, gravure printing, pad printing, etc. Prior art gravure processes employed cavities that were essentially the same volume, but varied the spacing between cavities. A series of second electrical conductors are also printed 350 using a high speed printing process, such as flexography, lithography, gravure, screen, or pad printing. The processes of filling the apertures 340 and printing the second electrical conductors 350 can be performed sequentially, in any order, or they can be performed at the same time, in a single operation. The net effect of printing a first electrical conductor, filling the aperture with conductive material, and printing a second electrical conductor is to create a vertical electrical connection through the dielectric layer. Finally, another set of electrical devices is situated 360 on the dielectric layer and the upper electrical conductors to form a multilayer circuit. This second level circuit is connected to the first level circuit by means of the printed three dimensional interconnect.

In summary, a printed multilayer electronic circuit that forms a three dimensional interconnect between two levels of circuitry can be created using high speed printing techniques such as flexography, lithography, gravure, screen, or pad printing. A series of electrical conductors are printed, then a layer of dielectric material is printed over these electrical conductors. The dielectric layer contains apertures openings that extend vertically through the dielectric layer down to the electrical conductors. A second set of electrical conductors are then printed on the dielectric layer, and electrically conductive material is printed in the apertures so that an electrical connection is made from the second set of electrical conductors to the electrical conductors on the lower level. The printing head contains cavities that vary in volume as a function of the amount of electrically conductive material to be filled in the apertures. In one embodiment, the substrate that supports the first level circuit is a temporary substrate, and is releasable from the built up multilayer structure. Those familiar with the art will appreciate that the invention could be applied to more than 2 layers. Multi-layer structures consisting of 3, 4 or more layers can be constructed by applying the process described in the invention. As the number of layers increases, the depth of the apertures can vary significantly, and the cavities in the printing head can be designed to accommodate variations in volume of ink required.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A printed multilayer electronic circuit, comprising:
a first level circuit, comprising first electronic components;
first electrical conductors printed on the first level circuit and electrically connected to one or more of the first electronic components;
a dielectric layer printed on the first electrical conductors, the dielectric layer containing one or more apertures situated on the first electrical conductors;
second electrical conductors printed on the dielectric layer, at least some of the second electrical conductors situated about at least one of the one or more apertures;
electrically conductive material printed in the one or more apertures sufficient to electrically connect the second electrical conductors to the first electrical conductors; and
a second level circuit, comprising second electronic components electrically connected to at least some of the first electronic components by means of the printed second electrical conductors, the printed electrically conductive material, and the printed first electrical conductors.

2. The printed multilayer electronic circuit as described in claim 1, wherein the first level circuit further comprises electrical conductors electrically connecting at least some of the first electronic components together.

3. The printed multilayer electronic circuit as described in claim 1, wherein the second level circuit further comprises electrical conductors electrically connecting at least some of the second electronic components together.

4. The printed multilayer electronic circuit as described in claim 1, wherein at least some of the one or more apertures are filled with the printed electrically conductive material.

5. The printed multilayer electronic circuit as described in claim 1, wherein the first and second electronic components comprise one or more components selected from the group consisting of printed transistors, printed emissive pixels, printed capacitors, printed resistors, printed inverters, printed ring oscillators, and printed reflective pixels.

6. A method of manufacturing a printed multilayer electronic circuit using high speed printing processes, comprising:
providing a first level circuit, comprising first electronic components;
printing first electrical conductors on the first level circuit such that the first electrical conductors are electrically connected to one or more of the first electronic components;
printing a dielectric layer containing apertures that are situated on the first electrical conductors;
printing second electrical conductors on the printed dielectric layer, wherein at least some of the second electrical conductors are situated on the apertures;
printing electrically conductive material in the apertures sufficient to electrically connect the second electrical conductors to the first electrical conductors;
wherein printing first electrical conductors, printing a dielectric layer, printing second electrical conductors, and printing electrically conductive material each comprises printing by means of a high speed printing process; and
providing a second level circuit on the printed dielectric layer, comprising second electronic components that are electrically connected to at least some of the first electronic components via the printed second electrical conductors, the printed electrically conductive material, and the printed first electrical conductors.

7. The method as described in claim 6, wherein providing a first level circuit further comprises providing electrical conductors electrically connecting at least some of the first electronic components together.

8. The method as described in claim 6, wherein providing a second level circuit further comprises providing electrical conductors electrically connecting at least some of the second electronic components together.

9. The method as described in claim 6, wherein printing electrically conductive material comprises filling the apertures with the printed electrically conductive material.

10. The method as described in claim 6, wherein the first and second electronic components comprise one or more components selected from the group consisting of printed transistors, printed emissive pixels, printed capacitors, printed resistors, printed inverters, printed ring oscillators, and printed reflective pixels.

11. The method as described in claim 6, wherein printing electrically conductive material comprises contact printing using a printing head having a plurality of cavities that contain the electrically conductive material to be printed, wherein the volume of the cavity varies as a function of the amount of electrically conductive material to be transferred into the aperture.

12. The method as described in claim 11, wherein printing electrically conductive material further comprises contact printing using a gravure printing process.

13. The method as described in claim 6, wherein printing by means of a high speed printing process further comprises printing by means of one or more printing processes selected from the group consisting of flexography, lithography, gravure, screen, and pad printing.

14. The method as described in claim 6, wherein the electrically conductive material in the apertures and the second electrical conductors are printed in a single printing process.

15. A printed multilayer electronic circuit, comprising:
a substrate having a plurality of first printed electronic devices situated thereon;
first electrical conductors printed on the substrate and electrically connected to one or more of the first printed electronic devices;
a dielectric layer containing apertures, printed on the first electrical conductors, the substrate, and the plurality of first printed electronic devices, such that the apertures are situated on the first electrical conductors;
second electrical conductors printed on the dielectric layer, at least some of the second electrical conductors situated about at least one of the apertures;
electrically conductive material printed in the apertures sufficient to electrically connect the second electrical conductors to the first electrical conductors; and
a plurality of second printed electronic devices situated on the dielectric layer and electrically connected to at least some of the first printed electronic devices through the printed second electrical conductors, the printed electrically conductive material, and the printed first electrical conductors.

16. The printed multilayer electronic circuit as described in claim 15, further comprising electrical conductors electrically connecting at least some of the first printed electronic devices together.

17. The printed multilayer electronic circuit as described in claim 15, further comprising electrical conductors electrically connecting at least some of the second printed electronic devices together.

18. The printed multilayer electronic circuit as described in claim 15, wherein at least some of the apertures are filled with the printed electrically conductive material.

19. The printed multilayer electronic circuit as described in claim 15, wherein the first and second printed electronic devices comprise one or more devices selected from the group consisting of printed transistors, printed emissive pixels, printed capacitors, printed resistors, printed inverters, printed ring oscillators, and printed reflective pixels.

20. The printed multilayer electronic circuit as described in claim 15, wherein the substrate is releasable.
The printed multilayer electronic circuit as described in claim 15, wherein the electrically conductive material printed in the apertures comprises a printed conductive aperture.
